(19) United States
(12) Patent Application Publication
(10) Pub. No.: US 2013/0098842 A1
(43) Pub. Date: Apr. 25, 2013

(54) METHOD FOR EVALUATING PERFORMANCE OF A LIME SOFTENING CLARIFIER

(71) Applicant: MOHAMMAD AMIRI, ISFAHAN (IR)

(72) Inventor: MOHAMMAD AMIRI, ISFAHAN (IR)

(21) Appl. No.: 13/279,372

(22) Filed: Oct. 24, 2011

(51) Int. Cl. C02F 5/06; G01R 27/08

(52) U.S. Cl. 210/702; 324/722

(57) ABSTRACT

The various embodiments herein provide a method for evaluating a performance of lime softening clarifiers. The method is based on electrical conductivity (EC) measurement of the treated water samples after addition of carbon dioxide. If EC of the treated water after carbon dioxide gas addition is lower than EC of the treated water, this shows an abnormal function of softening process and the lime dosage must be decreased. If EC of the treated water after carbon dioxide gas addition is higher than EC of the treated water, then the lime dosage is not enough and lime dosage must be increased. If EC of the treated water after carbon dioxide gas addition is roughly equal to EC of the said treated water, then the lime dosage is optimum and clarifier works in optimum condition.

### BACKGROUND

1. Technical Field

The embodiments herein generally relate to the field of water softening processes and more particularly to the methods of evaluating the performance of lime softening clarifiers.

2. Description of the Related Art

The hardness in water causes cost of millions and even billions of dollars annually due to heat loss and scaling in boilers and heat exchangers. Hardness has also fouling effects on reverse osmosis and other desalination units. Separation and removal of hardness ions is called softening Water softening is almost a common unit operation in many industries and makes the water suitable for using in cooling operation or prepares it for additional purification. Although total or partial removal of hardness ions is possible in various units such as reverse osmosis, electro dialysis, distillation or freezing, most industrial plants are struggling with water hardness by using two familiar separation processes: sedimentation i.e. lime or lime/soda and adsorption i.e. ion exchange.

Although it is a fact that lime softening for decreasing water hardness is an old and also voluminous process in the water utilities, it is still a cost-effective and also favorite process in some conditions. It requires high capital cost but is recommended especially when both the flow rate and the bicarbonate i.e. temporary hardness of raw water are high due to its lower operating cost.

In lime softening, calcium compounds in water are removed at a pH of about 9.0 to 9.5 while magnesium compounds require a pH of greater than 10. When soda ash is used to remove non-carbonate hardness, an even higher pH is required—10.0 to 10.5 for calcium compounds and 11.0 to 11.5 for magnesium compounds.

Currently, many lime clarifiers use only lime instead of lime and soda, as the main purpose is to decrease carbonate or temporary hardness not non-carbonate or permanent hardness because other methods for removing non-carbonate hardness are more attractive and cost effective than using soda in softening clarifier.

Control of softening process is important for a number of reasons. Firstly, consistent quality of the treated water with minimum hardness is most desirable. Secondly, optimal control results in minimum solid waste that must be disposed of. Finally, it reduces the operating costs of water treatment.

It is commonly accepted that lime dosage (and consequently pH) has a vital role on the performance of softening process.

Cold lime softening process can be traced to 1841, when Thomas Clark discovered that increasing the pH of water could partially reduce water hardness. The origin of lime softening dates back to 1841 when lime was added to Thames River water to reduce bicarbonate hardness by precipitation of calcium alkalinity as calcium carbonate and magnesium alkalinity as magnesium hydroxide. Modern day lime softening, referred to as the cold lime process, operates under the same principle. The softening process typically includes pretreatment, softening, recarbonation, and filtration steps. By adding hydrated lime, the following softening reactions occurs and results in precipitation of solid calcium carbonate and magnesium hydroxide:

2CO₂+Ca(OH)₂→Ca(HCO₃)₂ (1)

Ca²⁺+2HCO₃₋+Ca(OH)₂→2CaCO₃(s)+2H₂O (2)

Mg²⁺+2HCO₃+Ca(OH)₂→CaCO₃(s)+MgCO₃+2H₂O (3)

MgCO₃+Ca(OH)₂→CaCO₃(s)+Mg(OH)₂(s) (4)

MgSO₄+Ca(OH)₂→Mg(OH)₂+CaSO₄ (5)

CaSO₄+Na₂CO₃→CaCO₃+Na₂SO₄ (6)

The following facts are taken into consideration in lime softening process: generally in water, maximum percent of carbonate hardness is surely because of calcium bicarbonate but most non-carbonate hardness is because of magnesium salts. Removal of calcium hardness occurs in the first stage but mostly the removal of magnesium hardness occurs in the final stage of lime softening process. More lime is needed to create the necessary caustic alkalinity or higher pH for Mg(OH)₂ precipitation in the treatment basin. The lime softening is typically used for water containing low concentrations of non-carbonate hardness. Lime-soda softening may be required with high concentrations of non-carbonate hardness. Today, most softening processes use only lime and alternative choices such as lime-soda or hot lime-soda processes have been abandoned as these modern processes for removing residual hardness are economically more feasible. Solubility of both calcium carbonate and magnesium hydroxide is highly sensitive to pH and alkalinity, but although the solubility of magnesium hydroxide decreases in pHs more than 10, the solubility of calcium carbonate increases sharply at such high pH. Therefore regulating pH or alkalinity is a decisive factor in controlling the performance of lime clarifier.

But as the monitoring of pH is not simple, alkalinity or basicity is currently controlled as an indicator for optimum operating conditions. This is usually achieved by regulating working conditions in clarifier in such a manner that the double P-alkalinity of treated water is a little greater than M-alkalinity i.e., [symbol] P-M□ [symbol] ppm as [symbol] .

P-alkalinity is a measure of O̅H̅ and [symbol] concentrations but M-alkalinity is a measure of O̅H̅ and [symbol] and [symbol] concentrations and 2P-M=5 ppm is a measure for ensuring the O̅H̅ concentration is about 5 ppm not zero. However, (2P-M) determination is only an indirect indication of magnesium hardness concentration in water.

Although this method has been practiced for decades, but still it is not a successful and a trouble-free operation. However, in spite of its shortcomings, the method of control is currently used and a considerable amount of chemical waste water is generated during the various routine desirable titration tests. Thus there is a good opportunity to introduce a more confident approach for pledging minimum hardness and saving money and materials.

By adding hydrated lime the following reactions (softening) results in precipitation of solid calcium carbonate and magnesium hydroxide:

2CO [symbol] +Ca(OH)₂→Ca(HCO [symbol] )₂ (1)

Ca²⁺+2HCO₃⁻+Ca(OH)₂→2CaCO₃(s)+H₂O (2)

Mg²⁺+2HCO₃⁻+Ca(OH)₂→CaCO₃(s)+MgCO₃+2H₂O (3)

MgCO₃+Ca(OH)₂→CaCO₃(s)+Mg(OH)₂(s) (4)

Obviously, more lime is needed to create the necessary caustic alkalinity (higher pH) for Mg(OH)₂ precipitation in the treatment basin. Although theoretically “excess” lime is needed to increase the pH beyond 10.5 for production of magnesium hydroxide, such high pH can also be naturally evolved in injection zones of hydrated lime locally.

Solubility of both calcium carbonate and magnesium hydroxide is highly sensitive to pH, but although the solubility of magnesium hydroxide decreases at pH more than 10, the solubility of calcium carbonate increases sharply at such a high pH. Therefore regulating pH or alkalinity is a decisive factor in controlling the performance of lime clarifier.

It has also been recognized that the conductivity of water with addition of lime, initially progressively decreases to a minimum value due to precipitation of insoluble products but then increase due to excess lime in process. Therefore, approach to the optimum condition (minimum hardness and sludge) in lime clarifier can be checked by pH and/or conductivity.

Currently for simplicity, alkalinity rather than pH is usually controlled for checking optimum operating conditions. This is accomplished by keeping a positive value for (OH) concentration about 5 ppm as CaCO₃, that is, [symbol] P-M□ [symbol] ppm as [symbol] This corresponds to a pH of approximately 10.2-10.5.

Although conversion of all the bicarbonate into carbonate is necessary for ensuring the precipitation of solid calcium carbonate and magnesium hydroxide, this chemical system is too complex to pledge minimum hardness in the treated water. One aspect of this problem is due to the existence of some specific ions in water. For example, soluble aluminum in the softener effluent often interferes with softened water alkalinity titrations, even when very low levels of soluble aluminum exist. This interference, which necessitates an increase in lime feed, causes falsely low (2P-M) readings. However, in spite of this shortcoming, this method of control is currently used and a considerable amount of chemical waste water is generated during various titration tests. Therefore, a more confident approach for pledging minimum hardness in lime softening is highly desirable.

The above mentioned shortcomings, disadvantages and problems are addressed herein and which will be understood by reading and studying the following specification.

### OBJECTIVES OF THE EMBODIMENTS

The primary object of the embodiments herein is to provide a simple, easy and cost effective method for evaluating a performance of lime softening clarifiers.

Another object of the embodiments herein is to provide a method of checking an optimum operation condition of a lime softening clarifier.

Another object of the embodiments herein is to develop a method for evaluating a performance of the lime softening clarifiers using a physical process rather than using a chemical process.

Yet another object of the embodiments herein is to provide a method for evaluating a performance of lime softening clarifiers with no production of chemical waste.

Yet another object of the embodiments herein is to provide a method for evaluating a performance of lime softening clarifiers without usage of water for titrations.

Yet another object of the embodiments herein is to provide a cost effective and eco-friendly method for evaluating a performance of lime softening clarifiers.

These and other objects and advantages of the embodiments herein will become readily apparent from the following detailed description taken in conjunction with the accompanying drawings.

### SUMMARY

The various embodiments herein provide a new innovative method for controlling a performance of a lime softening process. The method involves using a physical process. The method includes the following steps of withdrawing a sample of the treated water, measuring the Electrical conductivity (EC) of the said treated water and adding carbon dioxide gas to the treated water, measuring the EC of this sample and controlling a lime dosage by comparing the two measured EC values. A performance of a softening process is judged as follows: If the EC of the treated water after carbon dioxide gas addition is lower than the EC of the said treated water, this shows an abnormal function of softening process and the added lime dosage must be decreased. If the EC of the treated water after carbon dioxide gas addition is higher than the EC of the said treated water, then the lime dosage added is not enough and the dose of lime must be increased. If the EC of the treated water after carbon dioxide gas addition is roughly equal to the EC of the said treated water, then the lime dosage amount is correct and a clarifier works in optimum condition.

The optimum operating condition of the softening process is checked accurately by an addition of the carbon dioxide gas to the treated water for the second time and checking whether the value of EC of the said water measured after the second time addition of the carbon dioxide gas is greater than the EC of water after the first time addition of the carbon dioxide gas but lower than EC of the second time addition of the carbon dioxide gas. Carbon dioxide gas is added to the treated water by blowing or puffing. The blowing or puffing is done by a short tube or by any other means of blowing.

According to one embodiment herein, a method for regulating a performance of a lime softening clarifier by controlling a lime dosage comprising the steps of withdrawing a sample of a treated water. The treated water is softened water obtained by adding a lime dosage. Then an electrical conductivity (EC 1) of the withdrawn sample is measured. A carbon dioxide gas is added to the withdrawn sample. An electrical conductivity 2 (EC 2) of the withdrawn sample after adding the carbon dioxide gas is measured. The electrical conductivity of the withdrawn sample after the addition of a lime dosage is compared with an electrical conductivity 2 (EC 2) of the withdrawn sample measured after adding the carbon dioxide gas for controlling a lime dosage. The lime dosage is controlled by comparing a value of the measured EC 1 with a value of the measured EC 2. The lime dosage is decreased, when the value of the measured EC 2 is lower than the value of the measured EC 1. The lime dosage is increased, when the value of the measured EC 2 is higher than the value of the measured EC 1. The lime dosage is found to be optimum, when the value of the measured EC 1 is roughly equal to the value of the measured EC 2. The method in the embodiments herein is based on an electrical conductivity (EC) measurement of the treated water. The treated water is obtained using a solid contact clarifier. The carbon dioxide gas is added by blowing or puffing in the withdrawn sample of the treated water. The blowing or puffing of the carbon dioxide is done by using a short tube or a straw or a capillary tube. The blowing or puffing of the carbon dioxide is done for 1-20 seconds and the blowing and puffing of the carbon dioxide is done preferably for 3-8 seconds. The carbon dioxide gas is added using a carbon dioxide cylinder source or adding saturated carbon dioxide water to the withdrawn sample of the treated water. The saturated carbon dioxide water is a fizzy drink.

A method for checking an optimum operation condition of a lime softening clarifier comprising the steps of withdrawing a sample of treated water. The treated water is softened water obtained by adding a lime dosage. An electrical conductivity 1 (EC 1) of the withdrawn sample is measured. A carbon dioxide gas is added to the withdrawn sample. An electrical conductivity 2 (EC 2) of the withdrawn sample after the addition of a carbon dioxide gas to the withdrawn sample is measured. The carbon dioxide gas is added for a second time. Again an electrical conductivity 3 (EC 3) of the withdrawn sample is measured after the addition of carbon dioxide gas for a second time and the optimum operation condition of the lime clarifier checked. The optimum operation condition of the lime clarifier is checked by comparing a value of the measured EC 1, a value of the measured EC 2 and a value of the measured EC 3. The optimum condition operation of the lime clarifier is found to be optimum when the value of the measured EC 1 is greater than the value of the measured EC 2 but less than the value of the measured EC 3. The treated water is obtained using a solid contact clarifier. The carbon dioxide gas is added by blowing or puffing carbon dioxide gas in the withdrawn sample of the treated water. The blowing or puffing of the carbon dioxide gas is done by using a short tube or a straw or a capillary tube. The blowing or puffing of the carbon dioxide gas is done for 1-20 seconds and wherein the blowing and puffing carbon dioxide gas is done preferably for 3-8 seconds. The carbon dioxide gas is added using a carbon dioxide cylinder source or by adding a saturated carbon dioxide water to the withdrawn sample of the treated water. The saturated carbon dioxide water is a fizzy drink.

According to another embodiment herein, a method of evaluating a performance of a lime softening clarifier comprising the steps of mixing an equal volume of a treated water and an untreated water to form a mixture. An electrical conductivity (EC) of the treated water measured. An electrical conductivity (EC) of the mixture is measured. The performance of the lime clarifier is evaluated by comparing a value of the measured EC of the treated water with a value of the measured EC of the mixture. A lime dosage in the lime clarifier is judged to be higher than an optimum dosage when the value of the measured EC of the mixture is less than the value of the measured EC of the treated water. A lime dosage in the lime clarifier is judged to be less than an optimum dosage when the value of the measured EC of the mixture is greater than the value of the EC of the treated water. A lime dosage is judged to be optimum when the value of the measured EC of the mixture is equal to the value of the measured EC of the treated water.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The other objects, features and advantages will occur to those skilled in the art from the following description of the preferred embodiment and the accompanying drawings in which:

FIG. 1 shows a flow chart illustrating the process steps in a method for regulating a performance of a lime softening clarifier, according to one embodiment herein.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### DETAILED DESCRIPTION OF THE EMBODIMENTS

In the following detailed description, a reference is made to the accompanying drawings that form a part hereof, and in which the specific embodiments that may be practiced is shown by way of illustration. The embodiments are described in sufficient detail to enable those skilled in the art to practice the embodiments and it is to be understood that the logical, mechanical and other changes may be made without departing from the scope of the embodiments. The following detailed description is therefore not to be taken in a limiting sense.

The various embodiments herein provide a method for regulating the performance of lime process or softening clarifier based on electrical conductivity (EC) measurement of treated or softened water. Lime softening is often used to reduce the hardness of water and sometimes to enhance clarification prior to filtration. Hardness is the sum of all multivalent ions, which are mainly of calcium and magnesium used for typical water treatment applications. Water is considered to be hard if it contains 150 mg/L as CaCO₃ or more. The method in the embodiments herein discloses a physical process instead of the currently used chemical process for controlling the performance of lime softening process.

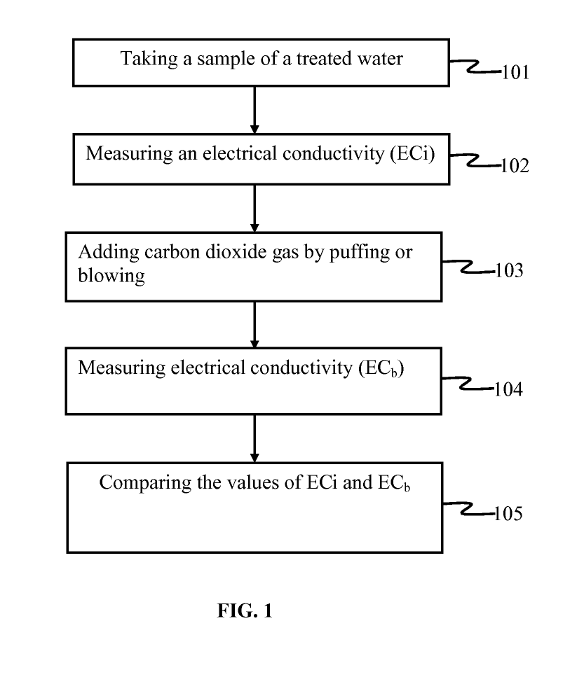

FIG.1 shows a flow chart explaining the process steps involved in a method for regulating a performance of a lime softening clarifier, according to one embodiment herein. With respect to FIG. 1, a sample of treated water is withdrawn (101). The treated water is softened water obtained by adding a lime dosage. An electrical conductivity (ECᵢ) of the withdrawn sample is measured (102). A carbon dioxide gas is added to the withdrawn sample (103). The carbon dioxide gas is added by blowing or puffing of carbon dioxide gas in the withdrawn sample of the treated water. The blowing or puffing of carbon dioxide gas is done by using a short tube or a straw or a capillary tube. The blowing or puffing of carbon dioxide gas is done for 1-20 seconds and wherein the blowing and puffing of carbon dioxide gas is done preferably for 3-8 seconds. According to another embodiment here, the carbon dioxide gas is added using a carbon dioxide cylinder source or adding saturated carbon dioxide water to the withdrawn sample of the treated water. The saturated carbon dioxide water is a fizzy drink. The electrical conductivity 2 (EC_{b}) of the treated water is measured after addition of carbon dioxide gas (104). The values of ECᵢ and EC_{b} are compared for controlling the lime dosage added to the water (105). The lime dosage is decreased, when the value of the measured EC_{b} is lower than the value of the measured ECᵢ. The lime dosage is increased, when the value of the measured EC_{b} is higher than the value of the measured ECᵢ. The lime dosage is found to be optimum, when the value of the measured ECᵢ is roughly equal to the value of the measured EC_{b}.

According to another embodiment herein, a method of regulating a performance of lime process comprises withdrawing a sample of the treated water, measuring the EC of treated water and adding carbon dioxide gas to the treated water, measuring the EC of this sample and controlling the lime dosage by comparing two measured ECs. The performance of a softening process is judged as follows: when EC of the treated water after carbon dioxide gas addition is lower than EC of the said treated water, then the lime dosage must be decreased. When EC of the treated water after carbon dioxide gas addition is higher than EC of the said treated water, then the lime dosage must be increased. When EC of the treated water after carbon dioxide gas addition is roughly equal to EC of the said treated water, then the lime dosage is found to be correct and clarifier works in optimum condition.

The optimum operation condition is checked accurately by an addition of carbon dioxide gas to the treated water for the second time and the value of EC of the said water is judged to be greater than EC measured after addition of carbon dioxide gas for first time but lower than EC measured after the addition of carbon dioxide gas for second time. The water treating process is done using a solids contact clarifier. The carbon dioxide gas addition to the treated water is done by blowing or puffing carbon dioxide done by using a short tube or a straw or a capillary tube for 1-20 seconds and preferably for 3-8 seconds.

According to the embodiments herein, the apparatus for puffing and blowing carbon dioxide gas is a short tube or any other means of blowing or puffing. Puffing time is 1-20 seconds or preferably 3-8 seconds. There is no need of using pure carbon dioxide and this is done simply and a free of charge by using blowing or puffing into the sample by a straw, tube or capillary for a few seconds. Introducing carbon dioxide into the sample is done directly from a CO₂ cylinder source, or from saturated CO₂ water such as in fizzy drinks.

According to an embodiment herein, a method for checking an optimum operation condition of a lime softening clarifier comprising the steps of withdrawing a sample of treated water. The treated water is softened water obtained by adding a lime dosage. An electrical conductivity 1 (EC 1) of the withdrawn sample is measured. A carbon dioxide gas is added to the withdrawn sample. An electrical conductivity 2 (EC 2) of the withdrawn sample after the addition of a carbon dioxide gas to the withdrawn sample is measured. The carbon dioxide gas is added for a second time. Again an electrical conductivity 3 (EC 3) of the withdrawn sample is measured after the addition of carbon dioxide gas for a second time and the optimum operation condition of the lime clarifier checked. The optimum operation condition of the lime clarifier is checked by comparing a value of the measured EC 1, a value of the measured EC 2 and a value of the measured EC 3. The optimum condition operation of the lime clarifier is found to be optimum when the value of the measured EC 1 is greater than the value of the measured EC 2 but less than the value of the measured EC 3. The treated water is obtained using a solid contact clarifier. The carbon dioxide gas is added by blowing or puffing carbon dioxide gas in the withdrawn sample of the treated water. The blowing or puffing of the carbon dioxide gas is done by using a short tube or a straw or a capillary tube. The blowing or puffing of the carbon dioxide gas is done for 1-20 seconds and wherein the blowing and puffing carbon dioxide gas is done preferably for 3-8 seconds. The carbon dioxide gas is added using a carbon dioxide cylinder source or by adding a saturated carbon dioxide water to the withdrawn sample of the treated water. The saturated carbon dioxide water is a fizzy drink.

According to another embodiment herein, a method of evaluating a performance of a lime softening clarifier comprising the steps of mixing an equal volume of a treated water and an untreated water to form a mixture. An electrical conductivity (EC) of the treated water measured. An electrical conductivity (EC) of the mixture is measured. The performance of the lime clarifier is evaluated by comparing a value of the measured EC of the treated water with a value of the measured EC of the mixture. A lime dosage in the lime clarifier is judged to be higher than an optimum dosage when the value of the measured EC of the mixture is less than the value of the measured EC of the treated water. A lime dosage in the lime clarifier is judged to be less than an optimum dosage when the value of the measured EC of the mixture is greater than the value of the EC of the treated water. A lime dosage is judged to be optimum when the value of the measured EC of the mixture is equal to the value of the measured EC of the treated water.

Electrical conductivity is a common, reliable and relatively of low cost test which is currently employed in each water treatment analysis. Therefore, no specific EC meter is required. Measuring the EC of the treated water sample and puffing into the treated water via a capillary tube for a few seconds and measuring the EC of this sample. Comparing these two measured ECs hints the operator to decide control lime dosage.

The concept behind this working condition is that all the bicarbonate ions must be converted to carbonate ions for having the least soluble form of calcium. Therefore, it is recommended that a slight excess of hydroxyl ion should be maintained in the treated water. The total dissolved solids (TDS) in raw water are contributed predominantly by seven major ions such as calcium, magnesium, sodium, bicarbonate, chloride, hydroxyl and sulfate. Softening reactions produce solid components that are finally removed from aqueous phase by a precipitation process. Therefore, the amount of TDS in softened water is decreased. EC is a surrogate measure of TDS. Reduction in total ions due to removing calcium, magnesium and bicarbonates is detected by measuring the conductivity of the aqueous phase. EC value can be obtained from in situ conductivity measurement. It is an intensive property that is measured currently for simple characterization of water, a quick reliable and relatively of low cost test and producing no chemical waste.

Excess hydrated lime has a decisive role on EC due to the following dissociation reaction:

Ca(OH)₂→ [symbol] +

[symbol]

Conductivity of OH⁻ is about 3 to 4 times more than of any other ions in lime process. In the final steps of softening process, hydroxyl ion has the primary role on EC. It can be used either to convert bicarbonate ion into carbonate ion (a slightly increase in EC) or used to precipitate magnesium ion into magnesium hydroxide (a considerable high decrease in EC). If it remains as a free excess ion and the excess OH⁻ ion promote higher pH but the solubility of calcium carbonate at higher pH is increased and EC of the treated water is increased sharply again due to the reappearance of Ca and CO₃ ions in aqueous phase. Hence, EC plays a vital role for understanding of microscopic reactions in softening process.

The results of the bench scale tests demonstrated clearly that minimum hardness in lime process is equivalent to minimum EC and this is the main finding of the embodiments herein for carrying out the process for evaluating the performance of lime softening clarifier.

Therefore, Electrical conductivity measurement (EC) data can be used for evaluating the performance of a softening process. The idea was applied for a full scale lime clarifier and was checked frequently and it was found that the workability of EC analysis for lime clarifier was more meaningful than alkalinity tests.

Contrary to the current method based on alkalinity, in no chemical waste is produced and no chemical materials or water is needed for titration as well as the cost of tests is sharply reduced the method disclosed in the embodiments herein. Therefore, it is highly eco-friendly and very cost effective alternative technique.

The main test in the embodiments herein is EC measurement. As a known art, common EC meters do not use any chemicals, and herefore, this is a physical method/process.

Thus EC, an intensive property that currently is measured for simple characterization of water and plays a vital role for understanding of microscopic reactions in softening process. EC can really probe the progress of softening reactions. Therefore, EC data should be used for evaluating the performance of softening process. The idea when checked with hundreds of operating data and the workability of EC analysis for lime clarifier was more meaningful than current method based on (2P-M) determination.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments.

It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

Although the embodiments herein are described with various specific embodiments, it will be obvious for a person skilled in the art to practice the invention with modifications. However, all such modifications are deemed to be within the scope of the claims.

It is also to be understood that the following claims are intended to cover all of the generic and specific features of the embodiments described herein and all the statements of the scope of the embodiments which as a matter of language might be said to fall there between.

What is claimed is:

1. A method for regulating a performance of a lime softening clarifier comprising the steps of:
withdrawing a sample of a treated water, wherein the treated water is a softened water obtained by adding a lime dosage;
measuring an electrical conductivity of the withdrawn sample;
adding a carbon dioxide gas to the withdrawn sample;
measuring an electrical conductivity of the withdrawn sample after adding the carbon dioxide gas; and
controlling a lime dosage, and wherein the lime dosage is controlled by comparing a value of the measured electrical conductivity of the withdrawn sample with a value of the measured electrical conductivity of the withdrawn sample after an addition of carbon dioxide gas, and wherein the lime dosage is judged to be optimum, when the value of the measured electrical conductivity of the withdrawn sample is equal to the value of the measured electrical conductivity of the withdrawn sample after the addition of carbon dioxide gas.

2. The method according to claim 1 further comprises decreasing the lime dosage when the value of the measured electrical conductivity of the withdrawn sample is less than the value of the measured electrical conductivity of the withdrawn sample after the addition of carbon dioxide gas.

3. The method according to claim 1 further comprises increasing the lime dosage when the value of the measured electrical conductivity of the withdrawn sample is more than the value of the measured electrical conductivity of the withdrawn sample after the addition of carbon dioxide gas.

4. The method according to claim 1, wherein the treated water is obtained using a solid contact clarifier.

5. The method according to claim 1, wherein the carbon dioxide gas is added by a blowing or puffing a carbon dioxide gas in the withdrawn sample of the treated water.

6. The method according to claim 5, wherein the blowing or puffing of carbon dioxide gas is done by using a short tube or a straw or a capillary tube.

7. The method according to claim 5, wherein the blowing or puffing carbon of dioxide gas is done for 1-20 seconds.

8. The method according to claim 5, wherein the blowing or puffing carbon of dioxide gas is done for 3-8 seconds.

9. The method according to claim 1, wherein the carbon dioxide gas is added using a carbon dioxide cylinder source or by adding a saturated carbon dioxide water to the withdrawn sample of the treated water, and wherein the saturated carbon dioxide water is a fizzy drink.

10. The method according to claim 1 further comprises checking an optimum operation condition of a lime softening clarifier comprising steps of:
withdrawing a sample of a treated water, wherein the treated water is a softened water obtained by adding a lime dosage;
measuring an electrical conductivity of the withdrawn sample;
adding a carbon dioxide gas for a first time to the withdrawn sample;
measuring an electrical conductivity of the withdrawn sample after adding a carbon dioxide gas for the first time;
adding the carbon dioxide gas for a second time to the withdrawn sample;
measuring an electrical conductivity of the withdrawn sample adding a carbon dioxide gas for the second time; and
checking an optimum operation condition of the lime clarifier, and wherein the optimum operation condition of the lime clarifier is checked by comparing a value of the measured electrical conductivity of the withdrawn sample, a value of the measured electrical conductivity of the withdrawn sample after adding a carbon dioxide gas for the first time and a value of the measured electrical conductivity of the withdrawn sample after adding a carbon dioxide gas for the second time, and wherein the optimum operation condition of the lime clarifier is judged to be optimum when the value of the measured electrical conductivity of the withdrawn sample is more than the value of the measured electrical conductivity of the withdrawn sample after adding a carbon dioxide gas for a first time but less than the value of the measured electrical conductivity of the withdrawn sample after adding a carbon dioxide gas for the second time.

11. A method of evaluating a performance of a lime softening clarifier comprising the steps of:
mixing an equal volume of a treated water and an untreated water to form a mixture;
measuring an electrical conductivity (EC) of the treated water;
measuring an electrical conductivity (EC) of the mixture;
evaluating a performance of the lime clarifier by comparing a value of the measured EC of the treated water with a value of the measured EC of the mixture, and wherein a lime dosage in the lime clarifier is judged to be more than an optimum dosage when the value of the measured EC of the mixture is less than the value of the measured EC of the treated water, and wherein a lime dosage in the lime clarifier is judged to be less than an optimum dosage when the value of the measured EC of the mixture is more than the value of the EC of the treated water, and wherein a lime dosage is judged to be an optimum dosage when the value of the measured EC of the mixture is equal to the value of the measured EC of the treated water.
